(19) United States
(12) Patent Application Publication
(10) Pub. No.: US 2021/0101826 A1
(43) Pub. Date: Apr. 8, 2021

(54) ANTIREFLECTIVE NANOPARTICLE COATINGS AND METHODS OF FABRICATION

(71) Applicant: WattGlass, Inc., Fayetteville, AR (US)

(72) Inventors: Corey S. Thompson, Springdale, AR (US); Robert A. Fleming, Fayettville, AR (US); Brennen M. Freiburger, Bentonville, AR (US)

(73) Assignee: WattGlass, Inc., Fayetteville, AR (US)

(21) Appl. No.: 16/872,849

(22) Filed: May 12, 2020

Related U.S. Application Data
(63) Continuation of application No. 15/598,979, filed on May 18, 2017, now abandoned.
(60) Provisional application No. 62/417,685, filed on Nov. 4, 2016.
(60) Provisional application No. 62/338,406, filed on May 18, 2016.

(51) Int. Cl. C03C 17/02; H02S 40/20; C03C 17/00; H01L 31/054; C03C 17/22; C03C 17/25; C03C 23/00; H01L 31/0216

(52) U.S. Cl. CPC C03C 17/02; C03C 2217/73; C03C 17/009; H01L 31/054; C03C 17/225; C03C 17/25; C03C 23/006; C03C 23/007; H01L 31/02168; C03C 2218/113; C03C 2218/32; Y02E 10/52; C03C 2217/732; C03C 2217/465; C03C 2217/213; C03C 2217/29; C03C 2217/425; H02S 40/20

(57) ABSTRACT

Antireflective nanoparticle coatings and methods of forming the coatings on substrates are disclosed. One method for forming an antireflective coating includes depositing a nanoparticle coating layer on a substrate, wherein the nanoparticle coating layer includes a colloidal solution of nanoparticles and a solidifying material. The solidifying material includes a silica precursor. The method further includes curing the solidifying material to form silica inter-particle connections between adjacent nanoparticles and between at least some of the nanoparticles and the substrate to bind the nanoparticles to each other and to the substrate to form the antireflective coating.

### CROSS REFERENCE TO RELATED APPLICATIONS

This application is a continuation of U.S. patent application Ser. No. 15/598,979 filed on May 18, 2017 entitled ANTIREFLECTIVE NANOPARTICLE COATINGS AND METHODS OF FABRICATION, which claims priority from U.S. Provisional Patent Application No. 62/338,406 filed on May 18, 2016 entitled ANTIREFLECTIVE NANOPARTICLE COATINGS AND METHODS OF FABRICATION and from U.S. Provisional Patent Application No. 62/417,685 filed on Nov. 4, 2016 entitled ANTIREFLECTIVE NANOPARTICLE COATINGS AND METHODS OF FABRICATION, all of which are hereby incorporated by reference.

### TECHNICAL FIELD

The present application relates generally to optical coatings and, more particularly, to nanoparticle coatings.

### BACKGROUND

Generally, an optical coating refers to a layer of material deposited on an optical component (e.g., lens, mirror, light source (e.g., laser, light emitting diode), solar cell, PV cover glass, optical detector, window glass, ophthalmologic lenses, or other optical components), which alters the way in which the optic reflects and transmits light. An antireflective (AR) coating is a type of the optical coating that is applied to the surface of the optical component to reduce reflection.

One type of the conventional AR coating is a multilayer AR coating. The multilayer AR coating includes alternating layers of a low-index material (e.g., silica) and a higher-index material deposited on top of each other to reduce reflectivity at a predetermined wavelength. The thicknesses of the layers of the multilayer AR coating are chosen to produce destructive interference in the beams reflected from the layers' interfaces, and constructive interference in the corresponding transmitted beams. Typically, the multilayer AR coatings that operate over a broad band of wavelengths, e.g., an infrared (IR), visible, or ultraviolet (UV) wavelength range, require complex design and are quite expensive.

Another type of the AR coating is a silica nanoparticles film that is deposited on a solar panel cover glass. The existing silica nanoparticle AR films, however, have limited durability and transmittance that negatively affects the performance and reliability of the solar panel. Additionally, in many cases silica nanoparticle AR films are based on sol-gel techniques that require the use of hazardous chemicals including acids and solvents.

### BRIEF SUMMARY

Various embodiments disclosed herein relate to methods for forming antireflective coatings on substrates such as optical components to alter the way in which the optical components reflect and/or transmit light. Such optical components can include, but are not limited to lenses, mirrors, light sources (e.g., laser, light emitting diode), solar cells, PV cover glass, optical detectors, window glass and ophthalmologic lenses.

In accordance with one or more embodiments, a method for forming an antireflective coating on a substrate includes the steps of: depositing a nanoparticle coating layer on the substrate, the nanoparticle coating layer comprising a colloidal solution of nanoparticles and a solidifying material, said solidifying material including a silica precursor; and curing the solidifying material to form silica inter-particle connections between adjacent nanoparticles and between at least some of the nanoparticles and the substrate to bind the nanoparticles to each other and to the substrate to form the antireflective coating.

An apparatus in accordance with one or more embodiments includes a substrate and a nanoparticle antireflective coating layer on the substrate. The nanoparticle antireflective coating layer comprises a plurality of nanoparticles bound by a solidifying material, and the antireflective coating layer includes pores therein.

In accordance with one or more embodiments, a method is disclosed for providing an antireflective coating on a substrate. The method includes the steps of: depositing an antireflective coating layer comprising nanoparticles on a substrate; forming pores in the antireflective coating layer; and thermally and/or chemically bonding adjacent nanoparticles in the antireflective coating layer. In accordance with one or more embodiments, the antireflective coating layer includes a surfactant, which is removed to create the pores. In accordance with one or more embodiments, the antireflective coating layer comprises less than 2 weight percent of the surfactant. In accordance with one or more embodiments, the surfactant modifies the surface tension of the coating solution to improve wettability resulting in improved coating uniformity and quality. In accordance with one or more embodiments, the antireflective coating layer includes a pore forming agent, which is removed to create the pores. In accordance with one or more embodiments, the antireflective coating layer comprises at least 0.01 weight percent of the pore forming agent. In accordance with one or more embodiments, the antireflective coating layer includes a surfactant and a pore forming agent, which are removed to create the pores. In accordance with one or more embodiments, the pores are formed using at least one of a heating process, a chemistry process, or a plasma process. In accordance with one or more embodiments, the method further comprises the step of tempering the substrate. In accordance with one or more embodiments, the nanoparticles comprise oxides, nitrides, oxynitrides, or fluorides of silicon, titanium, aluminum, boron, magnesium, strontium, lithium, or any combination thereof. In accordance with one or more embodiments, the nanoparticles comprise silica nanoparticles, aluminum oxide nanoparticles, titanium oxide nanoparticles, or any combination thereof. In accordance with one or more embodiments, a solution used to deposit the antireflective coating layer on the substrate comprises about 1 weight percent (wt %) to about 30 wt % of nanoparticles. In accordance with one or more embodiments, wherein after the pores are formed, the porosity of the antireflective coating layer is less than about 60%. In accordance with one or more embodiments, the antireflective coating layer is deposited using spray coating, dip coating, roll coating, or any combination thereof. In accordance with one or more embodiments, the thickness of the antireflective coating layer is from about 20 nanometers to about 500 nanometers. In accordance with one or more embodiments, the substrate is an optically transparent substrate.

In accordance with one or more further embodiments, a method is disclosed for providing a nanoparticle coating layer on a substrate. The method comprises the steps of: depositing the nanoparticle coating layer on a substrate, wherein the nanoparticle coating layer comprises nanoparticles and a surfactant; and removing the surfactant to create pores in the nanoparticle coating layer. In accordance with one or more embodiments, the surfactant is removed using a heating process. In accordance with one or more embodiments, the surfactant is removed using a chemistry process. In accordance with one or more embodiments, the surfactant is removed using plasma process. In accordance with one or more embodiments, the surfactant comprises a polymer. In accordance with one or more embodiments, the surfactant modifies the surface tension of the coating solution to improve wettability resulting in improved coating uniformity and quality. In accordance with one or more embodiments, the method further comprises the step of tempering the substrate, wherein the pores are created while the substrate is tempered. In accordance with one or more embodiments, the nanoparticles comprise oxides, nitrides, oxynitrides, or fluorides of silicon, titanium, aluminum, boron, magnesium, strontium, lithium, or any combination thereof. In accordance with one or more embodiments, the nanoparticle coating layer comprises silica nanoparticles, aluminum oxide nanoparticles, titanium oxide nanoparticles, or any combination thereof. In accordance with one or more embodiments, the solution used to deposit the nanoparticle coating layer comprises from about 1 wt % to about 30 wt % of the nanoparticles. In accordance with one or more embodiments, the nanoparticle coating layer comprises less than 2 weight percent of the surfactant. In accordance with one or more embodiments, the porosity of the nanoparticle coating layer is less than about 60% after the pores are created. In accordance with one or more embodiments, the nanoparticle coating layer is deposited using spray coating, dip coating, roll coating, or any combination thereof. In accordance with one or more embodiments, the thickness of the nanoparticle coating layer is from about 20 nanometers to about 500 nanometers. In accordance with one or more embodiments, the substrate is a glass substrate, an acrylic substrate, or any combination thereof. In accordance with one or more embodiments, the nanoparticle coating is an antireflective coating layer.

In accordance with one or more further embodiments, a method is disclosed for providing a nanoparticle coating layer on a substrate. The method comprises the steps of: depositing a nanoparticle coating layer on a substrate, wherein the nanoparticle coating layer comprises a pore forming agent; and removing the pore forming agent to create pores in the nanoparticle coating layer. In accordance with one or more embodiments, the pore forming agent is removed using a heating process. In accordance with one or more embodiments, the pore forming agent is removed using a chemistry process. In accordance with one or more embodiments, the pore forming agent is removed using plasma process. In accordance with one or more embodiments, the pore forming agent comprises a polymer. In accordance with one or more embodiments, the method further comprises the step of tempering the substrate, wherein the pores are created while the substrate is tempered. In accordance with one or more embodiments, wherein the nanoparticle coating layer comprises silica nanoparticles, aluminum oxide nanoparticles, titanium oxide nanoparticles, or any combination thereof. In accordance with one or more embodiments, a solution used to deposit the nanoparticle coating layer comprises from about 1 wt % to about 30 wt % of the nanoparticles. In accordance with one or more embodiments, the nanoparticle coating layer comprises at least 0.01 weight percent of the pore forming agent. In accordance with one or more embodiments, the porosity of the nanoparticle coating layer is less than about 60% after the pores are created. In accordance with one or more embodiments, the nanoparticle coating layer is deposited using spray coating, dip coating, roll coating, or any combination thereof. In accordance with one or more embodiments, the thickness of the nanoparticle coating layer is from about 20 nanometers to about 500 nanometers. In accordance with one or more embodiments, the substrate is a glass substrate, an acrylic substrate, or any combination thereof. In accordance with one or more embodiments, the nanoparticle coating is an antireflective coating layer.

In accordance with one or more further embodiments, a method is disclosed for providing a nanoparticle coating layer on a substrate. The method comprises the steps of: depositing a nanoparticle coating layer on a substrate, wherein the nanoparticle coating layer comprises a solidifying material; and curing the solidifying material to bind particles within the nanoparticle coating layer. In accordance with one or more embodiments, a solution used to deposit the nanoparticle coating layer comprises between 0.01 and 40 weight percent of the solidifying material. In accordance with one or more embodiments, the solidifying material is dehydrated by heating to a temperature greater than room temperature. In accordance with one or more embodiments, the solidifying material is cured by heating to a temperature greater than room temperature. In accordance with one or more embodiments, the solidifying material is cured through chemical reaction. In accordance with one or more embodiments, the solidifying material is cured through a reaction with carbon dioxide gas. In accordance with one or more embodiments, the carbon dioxide gas is provided from the ambient atmosphere. In accordance with one or more embodiments, the solidifying material comprises a silica precursor including but not limited to: alkoxysilanes, for example TEOS or TMOS; water soluble alkaline silicates comprising a cation such as an alkali metal, for example lithium, potassium, or sodium; a polyatomic ion, for example ammonium or hydronium; an organic ammonium ion, for example primary, secondary, tertiary, or quaternary ammonia cations; siloxanes; silsesquioxanes; and other silicon chain polymeric materials. In accordance with one or more embodiments, the method further comprises the step of tempering the substrate. In accordance with one or more embodiments, wherein the heat required to cure the solidifying material is provided during the tempering step. In accordance with one or more embodiments, wherein the solidifying material is cured at room temperature. In accordance with one or more embodiments, wherein the solidifying material cure process is initiated by the removal of stabilizing cations. In accordance with one or more embodiments, wherein the solidifying material cure process is initiated by the addition of acid. In accordance with one or more embodiments, wherein the acid is a carbonic acid formed from a CO2 atmosphere and water. In accordance with one or more embodiments, wherein the solidifying material cure process includes the production of silicic acid from a silica precursor. In accordance with one or more embodiments, wherein the solidifying material is converted to silicon dioxide through chemical processes. In accordance with one or more embodiments, the nanoparticles comprise oxides, nitrides, oxynitrides, or fluorides of silicon, titanium, aluminum, boron, magnesium, strontium, lithium, or any combination thereof. In accordance with one or more embodiments, wherein the nanoparticle coating layer comprises silica nanoparticles, aluminum oxide nanoparticles, titanium oxide nanoparticles, or any combination thereof. In accordance with one or more embodiments, a solution used to deposit the nanoparticle coating layer comprises from about 1 wt % to about 30 wt % of the nanoparticles. In accordance with one or more embodiments, the porosity of the nanoparticle coating layer is less than about 60% after the pores are created.

In accordance with one or more further embodiments, a method is disclosed for providing a nanoparticle coating layer on a substrate. The method comprises the steps of: depositing a nanoparticle coating layer on a substrate, wherein the nanoparticle coating layer comprises a pore forming agent and a surfactant; and removing the pore forming agent and surfactant to create pores in the nanoparticle coating layer. Wherein the nanoparticle coating layer further comprises a solidifying material; and curing the solidifying material to bind particles within the nanoparticle coating layer. In accordance with one or more embodiments, the antireflective coating layer includes a surfactant, which is removed to create the pores. In accordance with one or more embodiments, the surfactant modifies the surface tension of the coating solution to improve wettability resulting in improved coating uniformity and quality. In accordance with one or more embodiments, the antireflective coating layer includes a pore forming agent. In accordance with one or more embodiments, the pore forming agent comprises a polymer. In accordance with one or more embodiments, the antireflective coating layer comprises less than 2 weight percent of the surfactant. In accordance with one or more embodiments, the antireflective coating layer includes a pore forming agent, which is removed to create the pores. In accordance with one or more embodiments, the antireflective coating layer comprises at least 0.01 weight percent of the pore forming agent. In accordance with one or more embodiments, the antireflective coating layer includes a surfactant and a pore forming agent, which are removed to create the pores. In accordance with one or more embodiments, the pores are formed using at least one of a heating process, a chemistry process, or a plasma process. In accordance with one or more embodiments, the pore forming agent is removed using a heating process. In accordance with one or more embodiments, the pore forming agent is removed using a chemistry process. In accordance with one or more embodiments, the pore forming agent is removed using plasma process. In accordance with one or more embodiments, the method further comprises the step of tempering the substrate, wherein the pores are created while the substrate is tempered. In accordance with one or more embodiments, a solution used to deposit the nanoparticle coating layer comprises between 0.01 and 40 weight percent of the solidifying material. In accordance with one or more embodiments, the solidifying material is dehydrated by heating to a temperature greater than room temperature. In accordance with one or more embodiments, the solidifying material is cured by heating to a temperature greater than room temperature. In accordance with one or more embodiments, the solidifying material is cured through chemical reaction. In accordance with one or more embodiments, the solidifying material is cured through a reaction with carbon dioxide gas. In accordance with one or more embodiments, the carbon dioxide gas is provided from the ambient atmosphere. In accordance with one or more embodiments, the solidifying material comprises a silica precursor including but not limited to: alkoxysilanes, for example TEOS or TMOS; water soluble alkaline silicates comprising a cation such as an alkali metal, for example lithium, potassium, or sodium; a polyatomic ion, for example ammonium or hydronium; an organic ammonium ion, for example primary, secondary, tertiary, or quaternary ammonia cations; siloxanes; silsesquioxanes; and other silicon chain polymeric materials. In accordance with one or more embodiments, the method further comprises the step of tempering the substrate. In accordance with one or more embodiments, wherein the heat required to cure the solidifying material is provided during the tempering step. In accordance with one or more embodiments, wherein the solidifying material is cured at room temperature. In accordance with one or more embodiments, wherein the solidifying material cure process is initiated by the removal of stabilizing cations. In accordance with one or more embodiments, wherein the solidifying material cure process is initiated by the addition of acid. In accordance with one or more embodiments, wherein the acid is a carbonic acid formed from a CO2 atmosphere and water. In accordance with one or more embodiments, wherein the solidifying material cure process includes the production of silicic acid from a silica precursor. In accordance with one or more embodiments, wherein the solidifying material is converted to silicon dioxide through chemical processes. In accordance with one or more embodiments, the nanoparticles comprise oxides, nitrides, oxynitrides, or fluorides of silicon, titanium, aluminum, boron, magnesium, strontium, lithium, or any combination thereof. In accordance with one or more embodiments, wherein the nanoparticle coating layer comprises silica nanoparticles, aluminum oxide nanoparticles, titanium oxide nanoparticles, or any combination thereof. In accordance with one or more embodiments, a solution used to deposit the nanoparticle coating layer comprises from about 1 wt % to about 30 wt % of the nanoparticles. In accordance with one or more embodiments, the nanoparticle coating layer comprises at least 0.01 weight percent of the pore forming agent. In accordance with one or more embodiments, the porosity of the nanoparticle coating layer is less than about 60% after the pores are created.

In accordance with one or more further embodiments, a method is disclosed for providing a nanoparticle coating layer on a substrate. The method comprises the steps of: depositing a nanoparticle coating layer on a substrate, wherein the nanoparticle coating layer comprises a surfactant; and removing the surfactant to create pores in the nanoparticle coating layer. Wherein the nanoparticle coating layer further comprises a solidifying material; and curing the solidifying to bind particles within the nanoparticle coating layer. In accordance with one or more embodiments, the antireflective coating layer includes a surfactant, which is removed to create the pores. In accordance with one or more embodiments, the surfactant modifies the surface tension of the coating solution to improve wettability resulting in improved coating uniformity and quality. In accordance with one or more embodiments, the antireflective coating layer comprises less than 2 weight percent of the surfactant. In accordance with one or more embodiments, the pores are formed using at least one of a heating process, a chemistry process, or a plasma process. In accordance with one or more embodiments, the surfactant is removed using a heating process. In accordance with one or more embodiments, the surfactant is removed using a chemistry process. In accordance with one or more embodiments, the surfactant is removed using plasma process. In accordance with one or more embodiments, the surfactant is removed by evaporation. In accordance with one or more embodiments, the method further comprises the step of tempering the substrate, wherein the pores are created while the substrate is tempered. In accordance with one or more embodiments, a solution used to deposit the nanoparticle coating layer comprises between 0.01 and 40 weight percent of the solidifying material. In accordance with one or more embodiments, the solidifying material is dehydrated by heating to a temperature greater than room temperature. In accordance with one or more embodiments, the solidifying material is cured by heating to a temperature greater than room temperature. In accordance with one or more embodiments, the solidifying material is cured through chemical reaction. In accordance with one or more embodiments, the solidifying material is cured through a reaction with carbon dioxide gas. In accordance with one or more embodiments, the carbon dioxide gas is provided from the ambient atmosphere. In accordance with one or more embodiments, the solidifying material comprises a silica precursor including but not limited to: alkoxysilanes, for example TEOS or TMOS; water soluble alkaline silicates comprising a cation such as an alkali metal, for example lithium, potassium, or sodium; a polyatomic ion, for example ammonium or hydronium; an organic ammonium ion, for example primary, secondary, tertiary, or quaternary ammonia cations; siloxanes; silsesquioxanes; and other silicon chain polymeric materials. In accordance with one or more embodiments, the method further comprises the step of tempering the substrate. In accordance with one or more embodiments, wherein the heat required to cure the solidifying material is provided during the tempering step. In accordance with one or more embodiments, wherein the solidifying material is cured at room temperature. In accordance with one or more embodiments, wherein the solidifying material cure process is initiated by the removal of stabilizing cations. In accordance with one or more embodiments, wherein the solidifying material cure process is initiated by the addition of acid. In accordance with one or more embodiments, wherein the acid is a carbonic acid formed from a CO2 atmosphere and water. In accordance with one or more embodiments, wherein the solidifying material cure process includes the production of silicic acid from a silica precursor. In accordance with one or more embodiments, wherein the solidifying material is converted to silicon dioxide through chemical processes. In accordance with one or more embodiments, the nanoparticles comprise oxides, nitrides, oxynitrides, or fluorides of silicon, titanium, aluminum, boron, magnesium, strontium, lithium, or any combination thereof. In accordance with one or more embodiments, wherein the nanoparticle coating layer comprises silica nanoparticles, aluminum oxide nanoparticles, titanium oxide nanoparticles, or any combination thereof. In accordance with one or more embodiments, a solution used to deposit the nanoparticle coating layer comprises from about 1 wt % to about 30 wt % of the nanoparticles. In accordance with one or more embodiments, the porosity of the nanoparticle coating layer is less than about 60% after the pores are created.

In accordance with one or more further embodiments, a method is disclosed for providing a nanoparticle coating layer on a substrate. The method comprises the steps of: depositing a nanoparticle coating layer on a substrate, wherein the nanoparticle coating layer comprises a pore forming agent; and removing the pore forming agent to create pores in the nanoparticle coating layer. Wherein the nanoparticle coating layer further comprises a solidifying material; and curing the solidifying to bind particles within the nanoparticle coating layer. In accordance with one or more embodiments, the antireflective coating layer includes a pore forming agent, which is removed to create the pores. In accordance with one or more embodiments, the pore forming agent comprises a polymer. In accordance with one or more embodiments, the antireflective coating layer comprises at least 0.01 weight percent of the pore forming agent. In accordance with one or more embodiments, the pores are formed using at least one of a heating process, a chemistry process, or a plasma process. In accordance with one or more embodiments, the pore forming agent is removed using a heating process. In accordance with one or more embodiments, the pore forming agent is removed using a chemistry process. In accordance with one or more embodiments, the pore forming agent is removed using plasma process. In accordance with one or more embodiments, the method further comprises the step of tempering the substrate, wherein the pores are created while the substrate is tempered. In accordance with one or more embodiments, a solution used to deposit the nanoparticle coating layer comprises between 0.01 and 40 weight percent of the solidifying material. In accordance with one or more embodiments, the solidifying material is dehydrated by heating to a temperature greater than room temperature. In accordance with one or more embodiments, the solidifying material is cured by heating to a temperature greater than room temperature. In accordance with one or more embodiments, the solidifying material is cured through chemical reaction. In accordance with one or more embodiments, the solidifying material is cured through a reaction with carbon dioxide gas. In accordance with one or more embodiments, the carbon dioxide gas is provided from the ambient atmosphere. In accordance with one or more embodiments, the solidifying material comprises a silica precursor including but not limited to: alkoxysilanes, for example TEOS or TMOS; water soluble alkaline silicates comprising a cation such as an alkali metal, for example lithium, potassium, or sodium; a polyatomic ion, for example ammonium or hydronium; an organic ammonium ion, for example primary, secondary, tertiary, or quaternary ammonia cations; siloxanes; silsesquioxanes; and other silicon chain polymeric materials. In accordance with one or more embodiments, the method further comprises the step of tempering the substrate. In accordance with one or more embodiments, wherein the heat required to cure the solidifying material is provided during the tempering step. In accordance with one or more embodiments, wherein the solidifying material is cured at room temperature. In accordance with one or more embodiments, wherein the solidifying material cure process is initiated by the removal of stabilizing cations. In accordance with one or more embodiments, wherein the solidifying material cure process is initiated by the addition of acid. In accordance with one or more embodiments, wherein the acid is a carbonic acid formed from a CO2 atmosphere and water. In accordance with one or more embodiments, wherein the solidifying material cure process includes the production of silicic acid from a silica precursor. In accordance with one or more embodiments, wherein the solidifying material is converted to silicon dioxide through chemical processes. In accordance with one or more embodiments, the nanoparticles comprise oxides, nitrides, oxynitrides, or fluorides of silicon, titanium, aluminum, boron, magnesium, strontium, lithium, or any combination thereof. In accordance with one or more embodiments, wherein the nanoparticle coating layer comprises silica nanoparticles, aluminum oxide nanoparticles, titanium oxide nanoparticles, or any combination thereof. In accordance with one or more embodiments, a solution used to deposit the nanoparticle coating layer comprises from about 1 wt % to about 30 wt % of the nanoparticles. In accordance with one or more embodiments, the porosity of the nanoparticle coating layer is less than about 60% after the pores are created. In accordance with one or more embodiments, the nanoparticle coating layer is deposited using spray coating, dip coating, roll coating, or any combination thereof. In accordance with one or more embodiments, the thickness of the nanoparticle coating layer is from about 20 nanometers to about 500 nanometers. In accordance with one or more embodiments, the substrate is a glass substrate, an acrylic substrate, or any combination thereof. In accordance with one or more embodiments, the nanoparticle coating is an antireflective coating layer. In accordance with one or more embodiments, a device includes a substrate and a nanoparticle antireflective coating layer on the substrate. The nanoparticle antireflective coating layer includes pores.

Other features of the embodiments of the invention will be apparent from the accompanying drawings and from the detailed description which follows.

### BRIEF DESCRIPTION OF THE DRAWINGS

FIG. 1 illustrates a side view of a portion of an exemplary device having an antireflective coating according to one embodiment.

FIG. 2 illustrates a view similar to FIG. 1 after pores are formed in the ARC layer according to one embodiment.

FIG. 3 is a flowchart illustrating an exemplary method to provide an antireflective coating according to one embodiment.

FIG. 4 illustrates a side view of a portion of an exemplary device coated with the antireflective coating solution according to one embodiment.

FIG. 5 illustrates a view similar to FIG. 4 after the antireflective coating solution is evaporated.

FIG. 6 illustrates a higher magnification view of the antireflective coating similar to FIG. 5 showing particles and solidifying material after curing.

FIG. 7 is a flowchart illustrating an exemplary method to provide an antireflective coating according to one embodiment.

FIG. 8 shows an exemplary measurement of light transmittance of coated and uncoated glass substrates as a function of wavelength.

### DETAILED DESCRIPTION

Methods and apparatuses to provide an antireflective coating in accordance with various embodiments are described herein. An antireflective coating comprising nanoparticles is deposited on a substrate. Pores are formed in the antireflective coating. The antireflective coating layer is heated to create bonds between particles in the nanoparticle layer and to bond the antireflective coating layer to the substrate. Chemical reactions occur to achieve bonds between particles in the nanoparticle layer and to bond the antireflective coating to the substrate.

In one embodiment, the nanoparticle coating described herein effectively eliminates reflection, glare, and fogging on glass, acrylics and other transparent materials. In one embodiment, the nanoparticle coating described herein has self-cleaning properties. In one embodiment, the nanoparticle coating described herein is applied to translucent or opaque substrates to impart antifogging and self-cleaning behaviors. In one embodiment, the nanoparticle coating described herein photo-catalytically degrades organic soiling residing on the substrate. The nanoparticle coating is cost effective and can be used for many industries including, but not limited to automotive, consumer, building glass, and solar photovoltaic (PV) system industries.

In the following description, numerous specific details, such as specific materials, chemistries, dimensions of the elements, etc. are set forth in order to provide thorough understanding of various embodiments. It will be apparent, however, to one of ordinary skill in the art that the one or more embodiments may be practiced without these specific details. In other instances, some fabrication processes, techniques, materials, equipment, etc., have not been described in great details to avoid unnecessarily obscuring of this description. Those of ordinary skill in the art, with the included description, will be able to implement appropriate functionality without undue experimentation.

While certain exemplary embodiments are described and shown in the accompanying drawings, it is to be understood that such embodiments are merely illustrative and not restrictive, and that the embodiments of the invention are not restricted to the specific constructions and arrangements shown and described because modifications may occur to those ordinarily skilled in the art.

Reference throughout the specification to “one embodiment”, “another embodiment”, or “an embodiment” means that a particular feature, structure, or characteristic described in connection with the embodiment is included in at least one embodiment. Thus, the appearance of the phrases “in one embodiment” or “in an embodiment” in various places throughout the specification are not necessarily all referring to the same embodiment. Furthermore, the particular features, structures, or characteristics may be combined in any suitable manner in one or more embodiments.

Moreover, inventive aspects lie in less than all the features of a single disclosed embodiment. While the invention has been described in terms of several embodiments, those skilled in the art will recognize that the invention is not limited to the embodiments described, but can be practiced with modification and alteration within the spirit and scope of the appended claims. The description is thus to be regarded as illustrative rather than limiting.

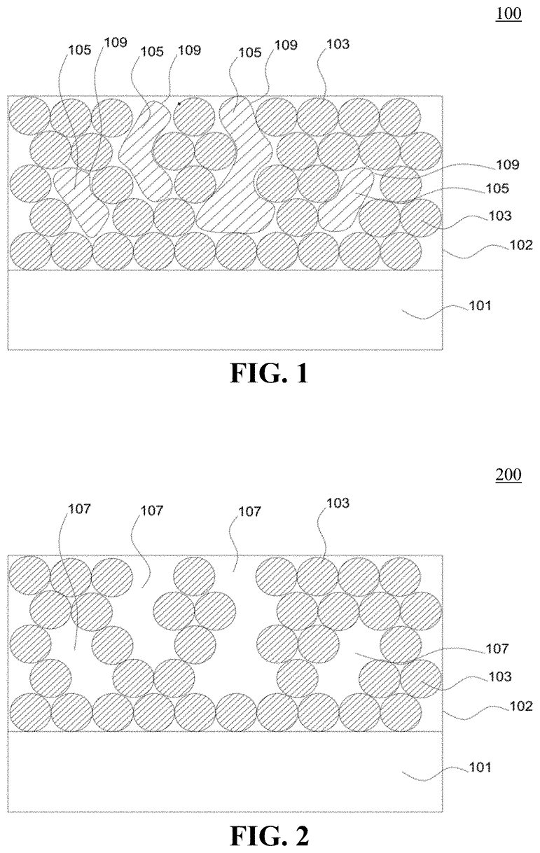

FIG. 1 shows a side view 100 of a portion of an apparatus comprising an antireflective coating according to one embodiment. The apparatus includes a substrate 101. An antireflective coating (ARC) layer 102 is deposited on substrate 101. The antireflective coating 102 comprises nanoparticles103 and a pore forming agent 105. Pore forming agent 105 is distributed between the nanoparticles, as shown in FIG. 1. In one embodiment, the pore forming agent 105 occupies spaces109 in the ARC layer 102 to form pores later on in a process, as described in further detail below. In one embodiment, the pore forming agent 105 is used to increase the porosity of the nanoparticle ARC layer 102, as described in further detail below. In one embodiment, the pore forming agent 105 is not removed from a later process. In an embodiment, an anti-reflective (“AR”) coating (not shown) is deposited on the passivation layer of a solar cell to reduce light loss due to reflection and to direct the light into the solar cell.

In one embodiment, the substrate 101 is an optically transparent substrate, e.g., a glass substrate, an acrylic substrate, a plastic substrate, a quartz substrate, a transparent ceramic substrate, or other optically transparent material substrate. In one embodiment, substrate 101 is a glass substrate having a refractive index n in an approximate range from about 1.4 to about 1.7. In more specific embodiment, the refractive index of the glass substrate 101 is about 1.5. In one embodiment, substrate 101 is a tempered glass substrate. In one embodiment, substrate 101 is a laminated glass substrate. In one embodiment, substrate 101 is a cover glass for a solar cell. In another embodiment, substrate 101 is a window glass. In alternative embodiments, substrate 101 includes a semiconductor material, e.g., silicon (“Si”), germanium (“Ge”), silicon germanium (“SiGe”), a III-V material, e.g., gallium arsenide (“GaAs”), or other semiconductor material. In one embodiment, substrate 101 includes metallization interconnect layers for integrated circuits. In one embodiment, substrate 101 includes electronic devices, e.g., transistors, memories, capacitors, resistors, optoelectronic devices, switches, and any other active and passive electronic devices that are separated by an electrically insulating layer. In an embodiment, substrate 101 includes an electrically insulating layer—e.g., an oxide layer, a nitride layer, or other electrically insulating layer determined by an electronic device design. In one embodiment, the insulating layer of the substrate 101 includes a spin-on-glass, an acrylic, a plastic, a polyimide, an epoxy, photodefinable materials, such as benzocyclobutene (BCB), and WPR-series materials, or other insulating materials.

In one embodiment, the nanoparticles of the ARC layer 102 are optically transparent nanoparticles. In one embodiment, the nanoparticles of the ARC layer 102 are silica nanoparticles. In one embodiment, the nanoparticles of the ARC layer 102 are silicon oxide nanoparticles. In yet another embodiment, the nanoparticles of the ARC layer are metal oxide nanoparticles, such as but not limited to titanium oxide, aluminum oxide, zinc oxide, cadmium stannate (Cd2SnO4), cadmium indate (CdIn2O4), zinc stannate (Zn2SnO4 and ZnSnOs), zinc indium oxide (Zn2In2O5), or any combination thereof. In alternative embodiments, the nanoparticles of the ARC layer 102 include but not limited to magnesium fluoride, carbon nanotubes, nanoclays, silicate glass nanoparticles, rare earth elements nanoparticles, fluorosilicate glass nanoparticles, fluoroborosilicate glass nanoparticles, aluminosilicate glass nanoparticles, calcium silicate glass nanoparticles, calcium aluminum silicate glass nanoparticles, calcium aluminum fluorosilicate glass, other optically transparent material nanoparticles, or any combination thereof.

In one embodiment, the size of the nanoparticles of the ARC layer 102 in at least one of the spatial dimensions (X, Y, Z) is on a nanometer scale. In one embodiment, the size of the nanoparticles of the ARC layer 102 in each of the three spatial dimensions (X, Y, Z) is on a nanometer scale. In one embodiment, the size of the nanoparticles of the ARC layer 102 is in an approximate range from about 1 nm to about 1000 nm. In more specific embodiment, the size of the nanoparticles of the ARC layer 102 is in an approximate range from about 10 nm to about 50 nm. In one embodiment, the largest size of the nanoparticles of the ARC layer 102 in each of the spatial dimensions is in an approximate range from about 1 nm to about 1000 nm. In more specific embodiment, the largest size of the nanoparticles of the ARC layer 102 in each of the spatial dimensions is in an approximate range from about 10 nm to about 50 nm. In one embodiment, the nanoparticles of the ARC layer 102 have a sphere-like shape, an oval shape, an elliptical shape, a triangular shape, a rectangular shape, a polygon shape, or other shape.

Generally, the surfactant is added to a water solution to reduce the surface tension. In one embodiment, the surfactant is used to increase uniformity of the ARC layer 102. In one embodiment, the surfactant is an organic surfactant, e.g., a polymeric surfactant, or other organic surfactant. In one embodiment, surfactant 105 is a nonionic surfactant, such as but not limited to a polyoxyethylene glycol, a polyoxypropylene glycol, polyoxyethylene glycol sorbitan alkyl esters, a block copolymer of polyethylene glycol and polypropylene glycol, e.g., poloxamer, and alcohol ethoxylates and propoxylates. In one embodiment, the surfactant is a mixture of a polypropylene glycol and a polyethylene glycol.

Generally, the pore forming agents are added to a silica coating to increase the porosity of the coating. In one embodiment, the pore forming agent is used to decrease the index of refraction of the ARC layer 102. In one embodiment, the pore forming agent is an organic nanoparticle, e.g., a polystyrene nanoparticle, a latex nanoparticle, or other organic nanoparticles. In one embodiment, the pore forming agent is an organic molecule, such as but not limited to polypropylene glycol, polyethylene glycol, copolymers of ethylene oxide and propylene oxide, or a block copolymer of polyethylene glycol and polypropylene glycol, e.g., poloxamer. In one embodiment, the pore forming agent is a mixture of organic molecules and organic nanoparticles.

In one embodiment, the nanoparticles and surfactant are substantially uniformly dispersed in a water based solution to form a colloidal suspension. In one embodiment, the colloidal suspension includes from about 1 weight percent (wt %) to about 30 wt % of nanoparticles and less than 2 wt % of the surfactant in a water solution. In one embodiment, the colloidal suspension includes from about 5 wt % to about 10 wt % of nanoparticles and at least from about 0.01 wt % to about 1 wt % of the surfactant in a water solution.

In one embodiment, the nanoparticles and pore forming agent are substantially uniformly dispersed in a water based solution to form a colloidal suspension. In one embodiment, the colloidal suspension includes from about 1 weight percent (wt %) to about 30 wt % of nanoparticles and at least about 0.1 wt % of the pore forming agent in a water solution. In one embodiment, the colloidal suspension includes from about 5 wt % to about 10 wt % of nanoparticles and at least from about 0.1 wt % to about 10 wt % of the pore forming agent in a water solution.

In one embodiment, the nanoparticles, surfactant and pore forming agent are substantially uniformly dispersed in a water based solution to form a colloidal suspension. In one embodiment, the colloidal suspension includes from about 1 weight percent (wt %) to about 30 wt % of nanoparticles, less than 2 wt % of the surfactant, and at least about 0.1 wt % of the pore forming agent in a water solution, In one embodiment, the colloidal suspension includes from about 5 wt % to about 10 wt % of nanoparticles, at least from about 0.01 wt % to about 1% wt of the surfactant, and at least from about 0.1 wt % to about 10 wt % of the pore forming agent in a water solution.

In one embodiment, depositing the ARC layer 102 involves depositing a water based solution including the nanoparticles and surfactant on the substrate 101. In one embodiment, the thickness of the water based solution including the nanoparticles and surfactant on the substrate 101 is from about 5 microns (μm) to about 10 μm. In one embodiment, the ARC layer 102 is deposited by coating the substrate 101 with the colloidal nanoparticle and surfactant solution using a dip coating, spray coating, roll coating, other colloidal solution deposition process, or any combination thereof. In one embodiment, the aqueous colloidal nanoparticle and surfactant solution after being deposited on the substrate 101 is dried at a room temperature, or at the temperature higher than the room temperature to remove water to form ARC layer 102. In one embodiment, the aqueous colloidal nanoparticle and surfactant solution deposited on the substrate 101 is dried at the temperature of at least 150 degrees C. to remove water. In one embodiment, the aqueous colloidal nanoparticle and surfactant solution deposited on the substrate 101 is dried at the temperature from about 150 degrees C. to about 250 degrees C. to remove water. In at least some embodiments, prior to depositing the colloidal nanoparticle solution, the substrate 101 is cleaned to remove any surface contamination using for example an ultra-sonication, a self-cleaning process, or other substrate cleaning process known to one of ordinary skill in the art. In one embodiment, the solution comprising the nanoparticles 103 and surfactant is deposited on the substrate 101 and then dried to form the ARC layer 102. In one embodiment, the thickness of the ARC layer 102 after the solution comprising the nanoparticles 103 and surfactant has been dried is in an approximate range from about 5 nm to about 500 nm. In another embodiment, the thickness of the ARC layer 102 in an approximate range from about 50 nm to about 200 nm. In more specific embodiment, the thickness of the ARC layer 102 is in an approximate range from about 100 nm to about 180 nm.

In one embodiment, depositing the ARC layer 102 involves depositing a water based solution including the nanoparticles 103, pore forming agent 105, and surfactant on the substrate 101. In one embodiment, the thickness of the water based solution including the nanoparticles 103, pore forming agent 105, and surfactant on the substrate 101 is from about 5 microns (μm) to about 10 μm. In one embodiment, the ARC layer 102 is deposited by coating the substrate 101 with the colloidal nanoparticle, pore forming agent, and surfactant solution using a dip coating, spray coating, roll coating, other colloidal solution deposition process, or any combination thereof. In one embodiment, the aqueous colloidal nanoparticle pore forming agent and surfactant solution after being deposited on the substrate 101 is (hied at a room temperature, or at the temperature higher than the room temperature to remove water to form ARE layer 102. In one embodiment, the aqueous colloidal nanoparticle pre forming agent and surfactant solution deposited on the substrate 101 is dried at the temperature of at least 150 degrees C. to remove water. In one embodiment, the aqueous colloidal nanoparticle, pore forming agent, and surfactant solution deposited on the substrate 101 is dried at the temperature from about 150 degrees C. to about 250 degrees C. to remove water. In at least some embodiments, prior to depositing the colloidal nanoparticle solution, the substrate 101 is cleaned to remove any surface contamination using for example an ultra-sonication, a self-cleaning process, or other substrate cleaning process known to one of ordinary skill in the art. In one embodiment, the solution comprising the nanoparticles 103, pore forming agent 105, and surfactant is deposited on the substrate 101 and then dried to form the ARC layer 102. In one embodiment, the thickness of the ARC layer 102 after the solution comprising the nanoparticles 103, pore forming agent 105, and surfactant has been dried is in an approximate range from about 5 nm to about 500 nm. In another embodiment, the thickness of the ARC layer 102 in an approximate range from about 50 nm to about 200 nm. In more specific embodiment, the thickness of the ARC layer 102 is in an approximate range from about 100 nm to about 180 nm.

In one embodiment, the pore forming agent 105 and surfactant comprise a single chemical composition. In one embodiment, the pore forming agent comprises poloxamer which is also a non-ionic surfactant.

FIG. 2 is a view 200 similar to FIG. 1 after pores are formed in the ARC layer according to one embodiment. As shown in FIG. 2, pore forming agent 105 is removed to form pores 107 in the ARC layer 102. In one embodiment, the size of the pores 107 is determined by the size of the spaces 109 respectively occupied by pore forming agent 105. In one embodiment, the size of the pore 107 is in an approximate range from about 1 nm to about 1000 nm. In one embodiment, the size of the pore 107 is in an approximate range from about 5 nm to about 100 nm. In more specific embodiment, the size of the pore 107 is in an approximate range from about 10 nm to about 50 nm.

In one embodiment, the pore forming agent 105 is burned off by heating the ARC layer 102 at a temperature greater than a room temperature for a predetermine time to sufficiently remove the pore forming agent from the pores. In one embodiment, the pore forming agent is burned off by heating the ARC layer 102 for at least from about 5 to about 10 seconds. In one embodiment, the temperature to burn off the pore forming agent to form pores in the ARC layer 102 is from about 500 degrees C. to about 450 degrees C. In another embodiment, the pore forming agent is etched out from the ARC layer 102 using a chemistry, for example, one or more solvents, acidic solutions, or leaching with water or deionized water. In yet another embodiment, pore forming agent 105 is removed from ARC layer 102 using plasma. Generally, plasma comprises particles (elements) e.g., atoms, molecular radicals and positive ions that are more chemically reactive than the molecular gases using which the plasma elements are produced. In one embodiment, pore forming agent 105 is removed to create the pores in the ARC layer 102 by a chemical reaction with plasma particles. In one embodiment, oxygen containing plasma particles oxidize the organic components of the pore forming agent, so that the pore forming agent is removed from the pores as a result of the oxidation. In one embodiment, the pores are formed by removing pore forming agent 105 while the glass substrate is tempered. Typically, a tempering process places the outer surfaces of the glass substrate into a state of compression and the core of the glass substrate into a state of tension. Such stresses cause the glass, when broken, to crumble into small granular chunks instead of splintering into jagged shards. Typically, the tempered glass is stronger and safer than an untempered glass. In one embodiment, a thermal tempering process involves pushing a glass substrate having the ARC layer 102 thereon on a roller table (conveyor) through a furnace. The ARC layer 102 on the glass substrate is heated by the furnace to a glass tempering temperature for a short time (e.g., one minute, or other short period of time). In one embodiment, the glass tempering temperature is in an approximate range from about 620 degrees C. to about 750 degrees C. In one embodiment, the pore forming agent 105 is burned off during the thermal tempering process when the temperature to heat the glass substrate having the ARC layer 102 thereon reaches about 500 degrees C. In one embodiment, after being heated to the tempering temperature, the ARC layer on the glass substrate is then rapidly cooled by a forced air cooling using a high pressured high speed air at a room temperature.

In one embodiment, the removal of the pore forming agent 105 increases the porosity of the nanoparticle ARC layer 102 by from about 5% to about 50% relative to the natural porosity of the nanoparticle layer. Generally, the porosity is referred to a ratio of the volume of the pores to the total volume of the nanoparticles of the ARC layer.

In one embodiment, after the pore forming agent 105 is removed, the porosity of the ARC layer 102 is in an approximate range from about 20 percent (%) to about 60%. In more specific embodiment, after the pore forming agent 105 is removed, the porosity of the ARC layer 102 is about 50 percent (%). In one embodiment, the refractive index of the ARC layer 102 is a function of porosity of the ARC layer. In one embodiment, the porosity of the ARC layer 102 is advantageously increased by increasing an amount of the surfactant in the ARC layer. In one embodiment, the index of refraction of the porous ARC layer is smaller than that of the ARC layer before forming the pores. That is, increasing the porosity of the ARC layer 102 as described herein increases a transmittance of the ARC layer 102 towards the underlying substrate comparing to the conventional nanoparticle ARC layers. In one embodiment, a glass substrate coated on opposing both sides with the porous ARC layer 102 has a transmittance peak of at least 98% occurring in a wavelength range from about 400 nm to about 1100 nm.

In one embodiment, the refractive index of the porous ARC layer 102 is between those of the substrate 101 and air to reduce reflection at the air-substrate interface. In one embodiment, the refractive index of the ARC layer 102 is from about 1.2 to about 1.3. In more specific embodiment, the refractive index of the ARC layer 102 is about 1.23.

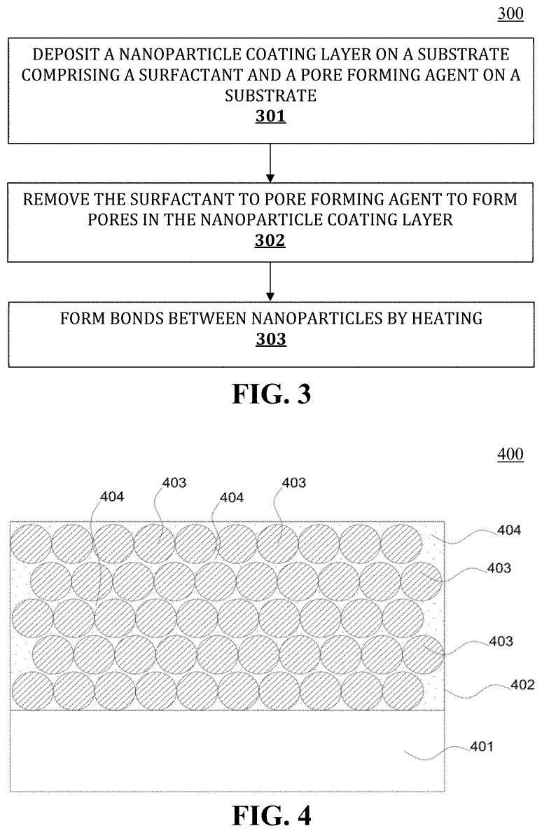

FIG. 3 is a flowchart 500 of a method to provide an antireflective coating according to one embodiment. At block 301 an ARC layer comprising nanoparticles, a forming agent, and surfactant is deposited on a substrate, as described above. At block 302 pores are formed in the ARC layer, as described above. At block 303 bonds are formed between adjacent nanoparticles comprising the antireflective coating layer by heating to a sufficient temperature. In one embodiment, the temperature is greater than 100 degrees C. and less than the softening point of the substrate. In a more specific embodiment, the nanoparticles are colloidal silica deposited on a glass substrate and require heating the coated substrate to a temperature of greater than 550 degrees C. and less than 750 degrees C. for bonding to occur. In one embodiment, this temperature is achieved during the glass tempering step. In one embodiment, this temperature is achieved during the glass annealing step.

FIG. 4 shows a side view 400 of a portion of an apparatus comprising an antireflective coating according to one embodiment. The apparatus includes a substrate 401. An antireflective coating (ARC) layer 402 is deposited on substrate 401. The antireflective coating 402 comprises nanoparticles 403 and a solidifying material solution 404. In one embodiment, a pore forming agent is distributed between the nanoparticles. In one embodiment, the pore forming agent occupies spaces in the ARC layer 402 to form pores later on in a process, as described in further detail below. In one embodiment, the pore forming agent is used to increase the porosity of the nanoparticle ARC layer 402, as described in further detail below. In one embodiment, the pore forming agent is not removed from a later process. The antireflective coating 402 further comprises a solution of solidifying material 404. In one embodiment, the solvent of the solution of solidifying material will be evaporated to deposit the solidifying material in a later on process. In one embodiment, the solution of solidifying material is a silica precursor that is cured in a later on process. In one embodiment, the solidifying material is used to increase the mechanical strength of the ARC layer 402, as described in further detail below.

In an embodiment, an anti-reflective (“AR”) coating (not shown) is deposited on the passivation layer of a solar cell to reduce light loss due to reflection and to direct the light into the solar cell.

In one embodiment, the substrate 401 is an optically transparent substrate, e.g., a glass substrate, an acrylic substrate, a plastic substrate, a quartz substrate, a transparent ceramic substrate, or other optically transparent material substrate. In one embodiment, substrate 401 is a glass substrate having a refractive index n in an approximate range from about 1.4 to about 1.7. In more specific embodiment, the refractive index of the glass substrate 401 is about 1.5. In one embodiment, substrate 401 is a tempered glass substrate. In one embodiment, substrate 401 is a laminated glass substrate. In one embodiment, substrate 401 is a cover glass for a solar cell. In another embodiment, substrate 401 is a window glass. In alternative embodiments, substrate 401 includes a semiconductor material, e.g., silicon (“Si”), germanium (“Ge”), silicon germanium (“SiGe”), a III-V material, e.g., gallium arsenide (“GaAs”), or other semiconductor material. In one embodiment, substrate 401 includes metallization interconnect layers for integrated circuits. In one embodiment, substrate 401 includes electronic devices, e.g., transistors, memories, capacitors, resistors, optoelectronic devices, switches, and any other active and passive electronic devices that are separated by an electrically insulating layer. In an embodiment, substrate 401 includes an electrically insulating layer—e.g., an oxide layer, a nitride layer, or other electrically insulating layer determined by an electronic device design. In one embodiment, the insulating layer of the substrate 401 includes a spin-on-glass, an acrylic, a plastic, a polyimide, an epoxy, photodefinable materials, such as benzocyclobutene (BCB), and WPR-series materials, or other insulating materials.

In one embodiment, the nanoparticles of the ARC layer 402 are optically transparent nanoparticles. In one embodiment, the nanoparticles of the ARC layer 402 are silica nanoparticles. In one embodiment, the nanoparticles of the ARC layer 402 are silicon oxide nanoparticles. In yet another embodiment, the nanoparticles of the ARC layer are metal oxide nanoparticles, such as but not limited to titanium oxide, aluminum oxide, zinc oxide, cadmium stannate (Cd2SnO4), cadmium indate (CdIn2O4), zinc stannate (Zn2SnO4 and ZnSnOs), zinc indium oxide (Zn2In2O5), or any combination thereof. In alternative embodiments, the nanoparticles of the ARC layer 402 include but not limited to magnesium fluoride, carbon nanotubes, nanoclays, silicate glass nanoparticles, rare earth elements nanoparticles, fluorosilicate glass nanoparticles, fluoroborosilicate glass nanoparticles, aluminosilicate glass nanoparticles, calcium silicate glass nanoparticles, calcium aluminum silicate glass nanoparticles, calcium aluminum fluorosilicate glass, other optically transparent material nanoparticles, or any combination thereof.

In one embodiment, the size of the nanoparticles of the ARC layer 402 in at least one of the spatial dimensions (X, Y, Z) is on a nanometer scale. In one embodiment, the size of the nanoparticles of the ARC layer 402 in each of the three spatial dimensions (X, Y, Z) is on a nanometer scale. In one embodiment, the size of the nanoparticles of the ARC layer 402 is in an approximate range from about 1 nm to about 1000 nm. In more specific embodiment, the size of the nanoparticles of the ARC layer 402 is in an approximate range from about 10 nm to about 50 nm. In one embodiment, the largest size of the nanoparticles of the ARC layer 402 in each of the spatial dimensions is in an approximate range from about 1 nm to about 1000 nm. In more specific embodiment, the largest size of the nanoparticles of the ARC layer 402 in each of the spatial dimensions is in an approximate range from about 10 nm to about 50 nm. In one embodiment, the nanoparticles of the ARC layer 402 have a sphere-like shape, an oval shape, an elliptical shape, a triangular shape, a rectangular shape, a polygon shape, or other shape.

Generally, the surfactant is added to a water solution to reduce the surface tension. In one embodiment, the surfactant is used to increase uniformity of the ARC layer 402. In one embodiment, the surfactant is an organic surfactant, e.g., a polymeric surfactant, or other organic surfactant. In one embodiment, surfactant 405 is a nonionic surfactant, such as but not limited to a polyoxyethylene glycol, a polyoxypropylene glycol, polyoxyethylene glycol sorbitan alkyl esters, a block copolymer of polyethylene glycol and polypropylene glycol, e.g., poloxamer, and alcohol ethoxylates and propoxylates. In one embodiment, the surfactant is a mixture of a polypropylene glycol and a polyethylene glycol.

Generally, the pore forming agents are added to a silica coating to increase the porosity of the coating. In one embodiment, the pore forming agent is used to decrease the index of refraction of the ARC layer 402. In one embodiment, the pore forming agent is an organic nanoparticle, e.g., a polystyrene nanoparticle, a latex nanoparticle, or other organic nanoparticles. In one embodiment, the pore forming agent is an organic molecule, such as but not limited to polypropylene glycol, polyethylene glycol, copolymers of ethylene oxide and propylene oxide, or a block copolymer of polyethylene glycol and polypropylene glycol, e.g., poloxamer. In one embodiment, the pore forming agent is a mixture of organic molecules and organic nanoparticles.

Generally, the solidifying material is added to a colloidal nanoparticle solution to bind the particles to each other and the underlying substrate. In one embodiment, the solidifying material is a silica precursor. In one embodiment, the solidifying material is a titanium dioxide precursor. In one embodiment, the solidifying material is a alkoxysilane, e.g., TEOS or TMOS. In one embodiment, the solidifying material is a water soluble alkaline silicate comprising a cation such as an alkali metal, i.e., lithium, potassium, or sodium; a polyatomic ion, i.e., ammonium or hydronium; an organic ammonium ion, i.e., primary, secondary, tertiary, or quaternary ammonia cations. In one embodiment, the solidifying material is a siloxane, silsesquioxanes, or other silicon chain polymeric materials.

In one embodiment, the solidifying material is substantially uniformly dispersed in a water based solution 404. In one embodiment, the solution of solidifying material 404 is introduced into the space between nanoparticles 403. In one embodiment, the solution of solidifying material is substantially uniformly dispersed in the antireflective coating solution. In one embodiment, the solution of solidifying material is co-deposited with the ARC coating layer.

In one embodiment, the solution of solidifying material 404 has a solids content of 0.01 to 40 weight percent. In a more specific embodiment, the concentration of the solidifying material is 0.1 to 10 weight percent. In one embodiment, the concentration of the solidifying material is 0.5 to 5.0 weight percent.

In one embodiment, the nanoparticles 403 and solidifying material 404 are substantially uniformly dispersed in a water based solution to form a colloidal suspension. In one embodiment, the colloidal suspension includes from about 1 weight percent (wt %) to about 30 wt % of nanoparticles and about 0.01 wt % to 40 wt % of the solidifying material. In one embodiment, the colloidal suspension includes from about 5 wt % to about 10 wt % of nanoparticles and from 0.5 wt % to 5 wt % of solidifying material in a water solution.

In one embodiment, the nanoparticles, surfactant, and solidifying material are substantially uniformly dispersed in a water based solution to form a colloidal suspension. In one embodiment, the colloidal suspension includes from about 1 weight percent (wt %) to about 30 wt % of nanoparticles, less than 2 wt % of the surfactant in a water solution, and about 0.01 wt % to 40 wt % of the solidifying material. In one embodiment, the colloidal suspension includes from about 5 wt % to about 10 wt % of nanoparticles, from about 0.01 wt % to about 1% wt % of the surfactant, and from 0.5 wt % to 5 wt % of solidifying material in a water solution.

In one embodiment, the nanoparticles, pore forming agent, and solidifying material are substantially uniformly dispersed in a water based solution to form a colloidal suspension. In one embodiment, the colloidal suspension includes from about 1 weight percent (wt %) to about 30 wt % of nanoparticles, at least about 0. 1 wt % of the pore forming agent in a water solution, and about 0.01 wt % to 40 wt % of the solidifying material. In one embodiment, the colloidal suspension includes from about 5 wt % to about 10 wt % of nanoparticles, from about 0.1 wt % to about 1% of the pore forming agent, and from 0.5 wt % to 5 wt % of solidifying material in a water solution.

In one embodiment, the nanoparticles, surfactant, pore forming agent, and solidifying material are substantially uniformly dispersed in a water based solution to form a colloidal suspension. In one embodiment, the colloidal suspension includes from about 1 weight percent (wt %) to about 30 wt % of nanoparticles, less than 2 wt % of the surfactant, at least about 0. 1wt % of the pore forming agent, and about 0.01 wt % to 40 wt % of the solidifying material in a water solution. In one embodiment, the colloidal suspension includes from about 5 wt % to about 10 wt % of nanoparticles, at least from about 0.01 wt % to about 1 wt % of the surfactant, at least from about 0.1 wt % to about 10 wt % of the pore forming agent, and from 0.5 wt % to 5 wt % of solidifying material in a water solution.

In one embodiment, depositing the ARC layer 402 involves depositing a water based solution including the nanoparticles, surfactant, and solidifying material on the substrate 401. In one embodiment, the thickness of the water based solution including the nanoparticles, surfactant, and solidifying material on the substrate 401 is from about 5 microns (μm) to about 10 μm. In one embodiment, the ARC layer 402 is deposited by coating the substrate 401 with the colloidal nanoparticle, surfactant, and solidifying material solution using a dip coating, spray coating, roll coating, other colloidal solution deposition process, or any combination thereof. In one embodiment, the aqueous colloidal nanoparticle, surfactant, and solidifying material solution after being deposited on the substrate 401 is dried at a room temperature, or at the temperature higher than the room temperature to remove water to form ARC layer 402. In one embodiment, the aqueous colloidal nanoparticle, surfactant solution, and solidifying material deposited on the substrate 401 is dried at the temperature of at least 150 degrees C. to remove water. In one embodiment, the aqueous colloidal nanoparticle and surfactant solution deposited on the substrate 401 is dried at the temperature from about 150 degrees C. to about 250 degrees C. to remove water. In at least some embodiments, prior to depositing the coating solution, the substrate 401 is cleaned to remove any surface contamination using for example an ultra-sonication, a self-cleaning process, or other substrate cleaning process known to one of ordinary skill in the art. In one embodiment, the solution comprising the nanoparticles 403, surfactant, and solidifying material is deposited on the substrate 401 and then dried to form the ARC layer 402. In one embodiment, the thickness of the ARC layer 402 after the solution comprising the nanoparticles 403, surfactant, and solidifying material has been dried is in an approximate range from about 5 nm to about 500 nm. In another embodiment, the thickness of the ARC layer 402 in an approximate range from about 50 nm to about 200 nm. In more specific embodiment, the thickness of the ARC layer 402 is in an approximate range from about 100 nm to about 180 nm.

In one embodiment, depositing the ARC layer 402 involves depositing a water based solution including the nanoparticles 403, pore forming agent, surfactant, and solidifying material on the substrate 401. In one embodiment, the thickness of the water based solution including the nanoparticles 403, pore forming agent, surfactant, and solidifying material on the substrate 401 is from about 5 microns (μm) to about 10 μm. In one embodiment, the ARC layer 402 is deposited by coating the substrate 401 with the colloidal nanoparticle, pore forming agent, and surfactant solution using a dip coating, spray coating, roll coating, other colloidal solution deposition process, or any combination thereof. In one embodiment, the aqueous colloidal nanoparticle, pore forming agent, surfactant solution, and solidifying material after being deposited on the substrate 401 is dried at a room temperature, or at the temperature higher than the room temperature to remove water to form ARC layer 402. In one embodiment, the aqueous colloidal nanoparticle, pore forming agent, surfactant, and solidifying material solution deposited on the substrate 401 is dried at the temperature of at least 150 degrees C. to remove water. In one embodiment, the aqueous colloidal nanoparticle, pore forming agent, surfactant, and solidifying material solution deposited on the substrate 401 is dried at the temperature from about 150 degrees C. to about 250 degrees C. to remove water. In at least some embodiments, prior to depositing the coating solution, the substrate 401 is cleaned to remove any surface contamination using for example an ultra-sonication, a self-cleaning process, or other substrate cleaning process known to one of ordinary skill in the art. In one embodiment, the solution comprising the nanoparticles 403, pore forming agent, surfactant, and solidifying material is deposited on the substrate 401 and then dried to form the ARC layer 402. In one embodiment, the thickness of the ARC layer 402 after the solution comprising the nanoparticles 403, pore forming agent, surfactant, and solidifying material has been dried is in an approximate range from about 5 nm to about 500 nm. In another embodiment, the thickness of the ARC layer 402 in an approximate range from about 50 nm to about 200 nm. In more specific embodiment, the thickness of the ARC layer 402 is in an approximate range from about 100 nm to about 180 nm.

In one embodiment, the pore forming agent and surfactant comprise a single chemical composition. In one embodiment, the pore forming agent comprises poloxamer which is also a non-ionic surfactant.

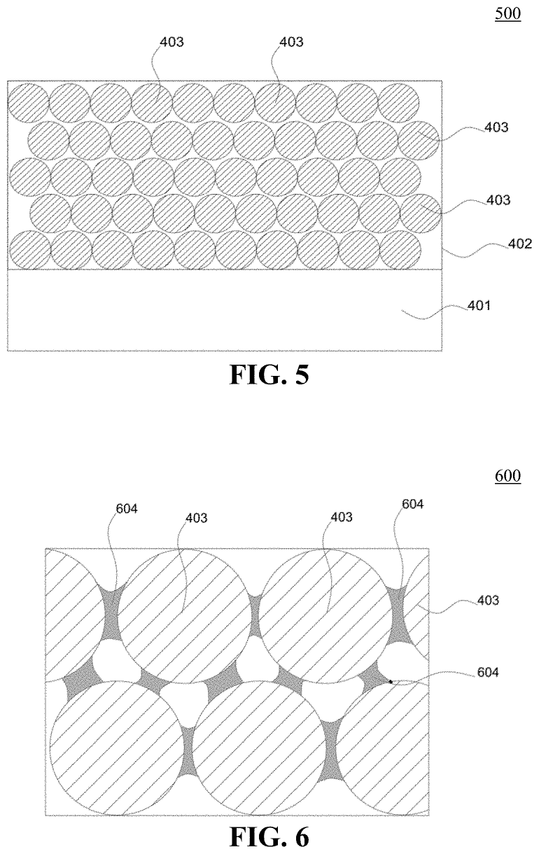

FIG. 5 is a view 500 similar to FIG. 4 after evaporation of the solidify material solution 404 in the ARC layer 402 according to one embodiment. As shown in FIG. 5, the solidifying material solution is evaporated resulting in deposition of the solidifying material in the spaces between adjacent nanoparticles 403. In one embodiment, the ARC layer 402 comprises a pore forming agent (not shown). In one embodiment, the ARC layer 402 comprises a surfactant (not shown).

In one embodiment, the solidifying material solution is a solution comprises 0.01 weight percent (wt %) to 40 wt % of solids. In a more specific embodiment, the solidifying solution comprises 0.5 wt % to 5 wt %.

In one embodiment, the solidifying material solution contains a precursor to the formation of silicon dioxide, or silica. In one embodiment, the silica precursor undergoes chemical reaction during the evaporation of the solidifying material solution. In one embodiment, the evaporation of solidifying material solution removes cations that stabilize the silica precursor, resulting in a chemical reaction. In one embodiment, stabilized silica precursor is deposited into the space between adjacent nanoparticles 403. In one embodiment, the stabilized silica precursor reacts with carbon dioxide in the ambient environment to form silica. In one embodiment, the stabilized silica precursor is caused to chemically react to form silica by heating. In one embodiment, the stabilized silica precursor is caused to chemically react to form silica by the introduction of another chemistry, i.e., acids, bases, salts, or solvents.

In one embodiment, the solidifying material is a silica precursor. In one embodiment, the solidifying material is a titanium dioxide precursor. In one embodiment, the solidifying material is a alkoxysilane, e.g., TEOS or TMOS. In one embodiment, the solidifying material is a water soluble alkaline silicate comprising a cation such as an alkali metal, i.e., lithium, potassium, or sodium; a polyatomic ion, i.e., ammonium or hydronium; an organic ammonium ion, i.e., primary, secondary, tertiary, or quaternary ammonia cations. In one embodiment, the solidifying material is a siloxane, silsesquioxanes, or other silicon chain polymeric materials.

In one embodiment, the pore forming agent is burned off by heating the ARC layer 402 for at least from about 5 to about 10 seconds. In one embodiment, the temperature to burn off the pore forming agent to form pores in the ARC layer 402 is from about 500 degrees C. to about 450 degrees C. In another embodiment, the pore forming agent is etched out from the ARC layer 402 using a chemistry, for example, one or more solvents, acidic solutions, or leaching with water or deionized water. In yet another embodiment, pore forming agent is removed from ARC layer 402 using plasma. Generally, plasma comprises particles (elements) e.g., atoms, molecular radicals and positive ions that are more chemically reactive than the molecular gases using which the plasma elements are produced. In one embodiment, pore forming agent is removed to create the pores in the ARC layer 402 by a chemical reaction with plasma particles. In one embodiment, oxygen containing plasma particles oxidize the organic components of the pore forming agent, so that the pore forming agent is removed from the pores as a result of the oxidation. In one embodiment, the pores are formed by removing pore forming agent while the glass substrate is tempered. Typically, a tempering process places the outer surfaces of the glass substrate into a state of compression and the core of the glass substrate into a state of tension. Such stresses cause the glass, when broken, to crumble into small granular chunks instead of splintering into jagged shards. Typically, the tempered glass is stronger and safer than an untempered glass. In one embodiment, a thermal tempering process involves pushing a glass substrate having the ARC layer 402 thereon on a roller table (conveyor) through a furnace. The ARC layer 402 on the glass substrate is heated by the furnace to a glass tempering temperature for a short time (e.g., one minute, or other short period of time). In one embodiment, the glass tempering temperature is in an approximate range from about 620 degrees C. to about 750 degrees C. In one embodiment, the pore forming agent is burned off during the thermal tempering process when the temperature to heat the glass substrate having the ARC layer 402 thereon reaches about 500 degrees C. In one embodiment, after being heated to the tempering temperature, the ARC layer on the glass substrate is then rapidly cooled by a forced air cooling using a high pressured high speed air at a room temperature.

In one embodiment, the removal of the pore forming agent increases the porosity of the nanoparticle ARC layer 402 by from about 5% to about 50% relative to the natural porosity of the nanoparticle layer. Generally, the porosity is referred to a ratio of the volume of the pores to the total volume of the nanoparticles of the ARC layer.

In one embodiment, after the pore forming agent is removed, the porosity of the ARC layer 402 is in an approximate range from about 20 percent (%) to about 60%. In more specific embodiment, after the pore forming agent is removed, the porosity of the ARC layer 402 is about 50 percent (%). In one embodiment, the refractive index of the ARC layer 402 is a function of porosity of the ARC layer. In one embodiment, the porosity of the ARC layer 402 is advantageously increased by increasing an amount of the surfactant in the ARC layer. In one embodiment, the index of refraction of the porous ARC layer is smaller than that of the ARC layer before forming the pores. That is, increasing the porosity of the ARC layer 402 as described herein increases a transmittance of the ARC layer 402 towards the underlying substrate comparing to the conventional nanoparticle ARC layers. In one embodiment, a glass substrate coated on opposing both sides with the porous ARC layer 402 has a transmittance peak of at least 98% occurring in a wavelength range from about 400 nm to about 1100 nm.

In one embodiment, the refractive index of the porous ARC layer 402 is between those of the substrate 401 and air to reduce reflection at the air-substrate interface. In one embodiment, the refractive index of the ARC layer 402 is from about 1.2 to about 1.3. In more specific embodiment, the refractive index of the ARC layer 402 is about 1.23.

FIG. 6 is a higher magnification view 600 of the ARC layer as shown in FIG. 5 after evaporation of the solidifying material solution. As shown in FIG. 6, the solidifying material in the space between nanoparticles 403 forms inter-particle connections 604 that impart mechanical rigidity to the coating. The configuration of inter-particle connections 604 shown in FIG. 6 is illustrative of the concept described in the embodiments of the invention, and should not be interpreted as the physical configuration of materials in the ARC layer after curing. The size, shape, and relative volume ratio of solidifying material to particles would be understood by one skilled in the art to be a function of the chemical interactions between the particles and the solidifying material, the concentration of solids of the solidifying material, and the method of cure.

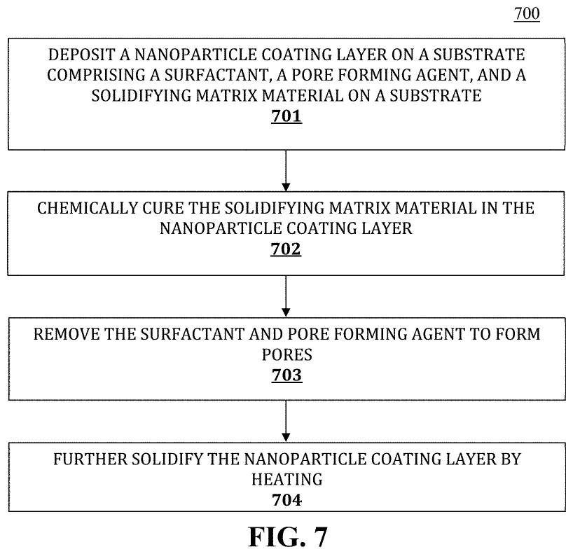

FIG. 7 is a flowchart 700 of a method to provide an antireflective coating according to one embodiment. At block 701 an ARC layer comprising nanoparticles, a pore forming agent, a surfactant, and a solidifying material is deposited on a substrate, as described above. At block 702 the solidifying material is cured to create a mechanically robust coating. At block 703 the pores are formed in the ARC layer, as described above. At block 704 the ARC coating is heated to a sufficient temperature to solidify the nanoparticle coating form bonds between adjacent nanoparticles comprising the antireflective coating layer. In one embodiment, the temperature is greater than 100 degrees C. and less than the softening point of the substrate. In a more specific embodiment, the nanoparticles are colloidal silica deposited on a glass substrate and heating the coated substrate to a temperature of greater than 550 degrees C. and less than 750 degrees C. imparts additional mechanical rigidity. In one embodiment, this temperature is achieved during the glass tempering step. In one embodiment, this temperature is achieved during the glass annealing step. In one embodiment, the process is comprised of one, all, or a combination of the blocks 701, 702, 703, and 704. In one embodiment, the order of blocks 702, 703, and 704 are interchangeable.

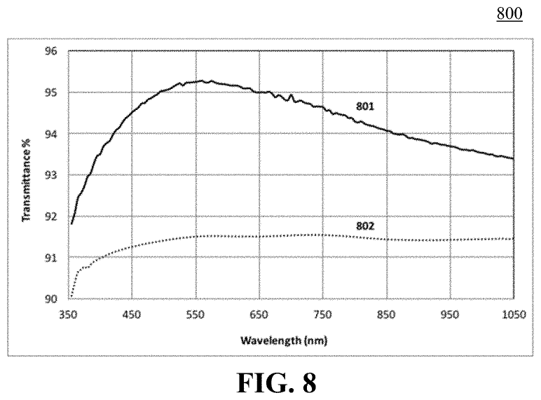

FIG. 8 is transmittance measurements of a glass substrate with an antireflective coating according to one embodiment 801 and a bare glass substrate 802. The coated substrate has a greater than 3.5% absolute increase in transmittance at 550 nm wavelength. The calculated solar weighted transmittance improvement of the coated substrate compared to the bare substrate is greater than 3.0%

The following examples pertain to further embodiments:

In one embodiment, a method to provide a nanoparticle coating layer comprises depositing the nanoparticle coating layer on a substrate, wherein the nanoparticle coating layer comprises a surfactant; and removing the surfactant to create pores in the nanoparticle coating layer.

In one embodiment, a method to provide a nanoparticle coating layer comprises depositing the nanoparticle coating layer on a substrate, wherein the nanoparticle coating layer comprises a surfactant; and removing the surfactant to create pores in the nanoparticle coating layer, wherein the surfactant is removed using a heating.

In one embodiment, a method to provide a nanoparticle coating layer comprises depositing the nanoparticle coating layer on a substrate, wherein the nanoparticle coating layer comprises a pore forming agent; and removing the pore forming agent to create pores in the nanoparticle coating layer, wherein the pore forming agent is removed using a heating.

In one embodiment, a method to provide a nanoparticle coating layer comprises depositing the nanoparticle coating layer on a substrate, wherein the nanoparticle coating layer comprises a surfactant; and removing the surfactant to create pores in the nanoparticle coating layer, wherein the surfactant is removed using a chemistry.

In one embodiment, a method to provide a nanoparticle coating layer comprises depositing the nanoparticle coating layer on a substrate, wherein the nanoparticle coating layer comprises a pore forming agent; and removing the pore forming agent to create pores in the nanoparticle coating layer, wherein the pore forming agent is removed using a chemistry.

In one embodiment, a method to provide a nanoparticle coating layer comprises depositing the nanoparticle coating layer on a substrate, wherein the nanoparticle coating layer comprises a surfactant; and removing the surfactant to create pores in the nanoparticle coating layer, wherein the surfactant is removed using plasma.

In one embodiment, a method to provide a nanoparticle coating layer comprises depositing the nanoparticle coating layer on a substrate, wherein the nanoparticle coating layer comprises a pore forming agent; and removing the pore forming agent to create pores in the nanoparticle coating layer, wherein the pore forming agent is removed using a plasma.

In one embodiment, a method to provide a nanoparticle coating layer comprises depositing the nanoparticle coating layer on a substrate, wherein the nanoparticle coating layer comprises a surfactant; and removing the surfactant to create pores in the nanoparticle coating layer, wherein the surfactant comprises a polymer.

In one embodiment, a method to provide a nanoparticle coating layer comprises depositing the nanoparticle coating layer on a substrate, wherein the nanoparticle coating layer comprises a pore forming agent; and removing the pore forming agent to create pores in the nanoparticle coating layer, wherein the pore forming agent comprises a polymer.

In one embodiment, a method to provide a nanoparticle coating layer comprises depositing the nanoparticle coating layer on a substrate, wherein the nanoparticle coating layer comprises a surfactant; tempering the substrate, and removing the surfactant to create pores in the nanoparticle coating layer, wherein the pores are created while the substrate is tempered.

In one embodiment, a method to provide a nanoparticle coating layer comprises depositing the nanoparticle coating layer on a substrate, wherein the nanoparticle coating layer comprises a pore forming agent; tempering the substrate, and removing the pore forming agent to create pores in the nanoparticle coating layer, wherein the pores are created while the substrate is tempered.

In one embodiment, a method to provide a nanoparticle coating layer comprises depositing the nanoparticle coating layer on a substrate, wherein the nanoparticle coating layer comprises a surfactant; and removing the surfactant to create pores in the nanoparticle coating layer, wherein the nanoparticle coating layer comprises silica nanoparticles, aluminum oxide nanoparticles, titanium oxide nanoparticles, or any combination thereof.

In one embodiment, a method to provide a nanoparticle coating layer comprises depositing the nanoparticle coating layer on a substrate, wherein the nanoparticle coating layer comprises a pore forming agent; and removing the surfactant to create pores in the nanoparticle coating layer, wherein the nanoparticle coating layer comprises silica nanoparticles, aluminum oxide nanoparticles, titanium oxide nanoparticles, or any combination thereof.

In one embodiment, a method to provide a nanoparticle coating layer comprises depositing the nanoparticle coating layer on a substrate, wherein the nanoparticle coating layer comprises a surfactant; and removing the surfactant to create pores in the nanoparticle coating layer, wherein the solution used to deposit the nanoparticle coating layer comprises about 1 weight percent (wt %) to about 30 wt % of the nanoparticles.

In one embodiment, a method to provide a nanoparticle coating layer comprises depositing the nanoparticle coating layer on a substrate, wherein the nanoparticle coating layer comprises a pore forming agent; and removing the pore forming agent to create pores in the nanoparticle coating layer, wherein the solution used to deposit the nanoparticle coating layer comprises about 1 weight percent (wt %) to about 30 wt % of the nanoparticles.

In one embodiment, a method to provide a nanoparticle coating layer comprises depositing the nanoparticle coating layer on a substrate, wherein the nanoparticle coating layer comprises a surfactant; and removing the surfactant to create pores in the nanoparticle coating layer, wherein the nanoparticle coating layer comprises less than 2 weight percent of the surfactant.

In one embodiment, a method to provide a nanoparticle coating layer comprises depositing the nanoparticle coating layer on a substrate, wherein the nanoparticle coating layer comprises a pore forming agent; and removing the pore forming agent to create pores in the nanoparticle coating layer, wherein the nanoparticle coating layer comprises at least 0.01 weight percent of the pore forming agent.

In one embodiment, a method to provide a nanoparticle coating layer comprises depositing the nanoparticle coating layer on a substrate, wherein the nanoparticle coating layer comprises a surfactant; and removing the surfactant to create pores in the nanoparticle coating layer, wherein porosity of the nanoparticle coating layer is about 50 percent after the pores are created.

In one embodiment, a method to provide a nanoparticle coating layer comprises depositing the nanoparticle coating layer on a substrate, wherein the nanoparticle coating layer comprises a pore forming agent; and removing the pore forming agent to create pores in the nanoparticle coating layer, wherein porosity of the nanoparticle coating layer is about 50 percent after the pores are created.

In one embodiment, a method to provide a nanoparticle coating layer comprises depositing the nanoparticle coating layer on a substrate, wherein the nanoparticle coating layer comprises a surfactant; and removing the surfactant to create pores in the nanoparticle coating layer, wherein the nanoparticle coating layer is deposited using spray coating, dip coating, roll coating or any combination thereof.

In one embodiment, a method to provide a nanoparticle coating layer comprises depositing the nanoparticle coating layer on a substrate, wherein the nanoparticle coating layer comprises a pore forming agent; and removing the pore forming agent to create pores in the nanoparticle coating layer, wherein the nanoparticle coating layer is deposited using spray coating, dip coating, roll coating or any combination thereof.

In one embodiment, a method to provide a nanoparticle coating layer comprises depositing the nanoparticle coating layer on a substrate, wherein the nanoparticle coating layer comprises a surfactant; and removing the surfactant to create pores in the nanoparticle coating layer, wherein the thickness of the nanoparticle coating layer is from about 20 nanometers to about 500 nanometers.

In one embodiment, a method to provide a nanoparticle coating layer comprises depositing the nanoparticle coating layer on a substrate, wherein the nanoparticle coating layer comprises a pore forming agent; and removing the pore forming agent to create pores in the nanoparticle coating layer, wherein the thickness of the nanoparticle coating layer is from about 20 nanometers to about 500 nanometers.

In one embodiment, a method to provide a nanoparticle coating layer comprises depositing the nanoparticle coating layer on a substrate, wherein the nanoparticle coating layer comprises a surfactant; and removing the surfactant to create pores in the nanoparticle coating layer, wherein the substrate is a glass substrate, an acrylic substrate, or any combination thereof.

In one embodiment, a method to provide a nanoparticle coating layer comprises depositing the nanoparticle coating layer on a substrate, wherein the nanoparticle coating layer comprises a pore forming agent; and removing the pore forming agent to create pores in the nanoparticle coating layer, wherein the substrate is a glass substrate, an acrylic substrate, or any combination thereof.

In one embodiment, a method to provide a nanoparticle coating layer comprises depositing the nanoparticle coating layer on a substrate, wherein the nanoparticle coating layer comprises a surfactant; and removing the surfactant to create pores in the nanoparticle coating layer, wherein the nanoparticle coating is an antireflective coating layer.

In one embodiment, a method to provide a nanoparticle coating layer comprises depositing the nanoparticle coating layer on a substrate, wherein the nanoparticle coating layer comprises a pore forming agent; and removing the pore forming agent to create pores in the nanoparticle coating layer, wherein the nanoparticle coating is an antireflective coating layer.

In one embodiment, an apparatus comprises a substrate; a nanoparticle antireflective coating layer on the substrate, wherein the nanoparticle antireflective coating layer comprises pores.

In one embodiment, an apparatus comprises a substrate; a nanoparticle antireflective coating layer on the substrate, wherein the nanoparticle antireflective coating layer comprises pores, wherein the size of the pores is determined by the size of the space occupied by a surfactant.

In one embodiment, an apparatus comprises a substrate; a nanoparticle antireflective coating layer on the substrate, wherein the nanoparticle antireflective coating layer comprises pores, wherein the size of the pores is determined by the size of the space occupied by a pore forming agent.

In one embodiment, an apparatus comprises a substrate; a nanoparticle antireflective coating layer on the substrate, wherein the nanoparticle antireflective coating layer comprises pores, wherein the substrate is a glass substrate, an acrylic substrate, or any combination thereof.

In one embodiment, an apparatus comprises a substrate; a nanoparticle antireflective coating layer on the substrate, wherein the nanoparticle antireflective coating layer comprises pores, wherein the nanoparticle antireflective coating layer comprises silica nanoparticles, aluminum oxide nanoparticles, titanium oxide nanoparticles, or any combination thereof.

In one embodiment, an apparatus comprises a substrate; a nanoparticle antireflective coating layer on the substrate, wherein the nanoparticle antireflective coating layer comprises pores, wherein the solution used to deposit the nanoparticle antireflective coating layer comprises about 1 weight percent (wt %) to about 30 wt % of the nanoparticles.

In one embodiment, an apparatus comprises a substrate; a nanoparticle antireflective coating layer on the substrate, wherein the nanoparticle antireflective coating layer comprises pores, wherein the porosity of the nanoparticle antireflective coating layer is less than about 60%.

In one embodiment, an apparatus comprises a substrate; a nanoparticle antireflective coating layer on the substrate, wherein the nanoparticle antireflective coating layer comprises pores, wherein the thickness of the nanoparticle antireflective coating layer is in a range from about 20 nanometers to about 500 nanometers.

In the foregoing specification, embodiments of the invention have been described with reference to specific exemplary embodiments thereof. It will be evident that various modifications may be made thereto without departing from the broader spirit and scope of the embodiments of the invention. The specification and drawings are accordingly, to be regarded in an illustrative sense rather than a restrictive sense.

1. A method of forming an antireflective coating on a substrate, comprising the steps of:
depositing a nanoparticle coating layer on the substrate, the nanoparticle coating layer comprising a colloidal solution of nanoparticles and a solidifying material, said solidifying material including a silica precursor; and
curing the solidifying material to form silica inter-particle connections between adjacent nanoparticles and between at least some of the nanoparticles and the substrate to bind the nanoparticles to each other and to the substrate to form the antireflective coating.

2. The method of claim 1, wherein the solidifying material comprises a dilute water-based solution of silica precursor.

3. The method of claim 1, wherein the silica precursor is a precursor selected from the group consisting of alkoxysilanes, siloxanes, silsesquioxanes, polysiloxanes, polysilazanes, and water soluble alkaline silicates.

4. The method of claim 1, wherein the silica precursor is a water soluble silicate comprising a cation selected from the group consisting of alkali metal ions, polyatomic ions, ammonium ions, amines, and organic ammonium ions.

5. The method of claim 1, wherein the solidifying material is cured by heating the nanoparticle coating layer.

6. The method of claim 1, wherein the solidifying material is cured at room temperature in an ambient environment.

7. The method of claim 1, wherein the solidifying material is cured by removing cations to form silica.

8. A method of claim 7, wherein the cations are removed by conversion of ammonium ions to gaseous ammonia.

9. The method of claim 1, wherein the solidifying material is cured by introducing another chemical to cause reaction of the silica precursor to form silica.

10. The method of claim 1, wherein the solidifying material is cured by reaction with an acid to form silica.

11. The method of claim 10, wherein the acid is a carbonic acid formed from a CO2 atmosphere and water.

12. The method of claim 1, wherein curing the solidifying material comprises producing silicic acid from the silica precursor.

13. The method of claim 1, wherein the nanoparticle coating layer further comprises a surfactant and/or a pore forming agent.

14. The method of claim 13, further comprising removing the surfactant and/or the pore forming agent.

15. The method of claim 14, wherein the surfactant and/or the pore forming agent are removed by an evaporation process, a heating process, a chemistry process, or a plasma process.

16. The method of claim 1, wherein the nanoparticles comprise oxides, nitrides, oxynitrides, or fluorides of silicon, titanium, aluminum, boron, magnesium, strontium, lithium, or any combination thereof.

17. The method of claim 1, wherein the nanoparticles comprise silica nanoparticles.

18. An antireflective coating produced by the method of claim 1.

19. An apparatus comprising:
a substrate; and
a nanoparticle antireflective coating layer on the substrate, wherein the nanoparticle antireflective coating layer comprises a plurality of nanoparticles bound by a solidifying material, wherein the antireflective coating layer includes pores therein.

20. The apparatus of claim 19, wherein the substrate is a glass substrate, a semiconductor substrate, a ceramic substrate, a polymer substrate, or any combination thereof.

21. The apparatus of claim 19, where the nanoparticle antireflective coating layer comprises oxides, nitrides, flourides, or oxynitrides of silicon, aluminum, magnesium, lithium, titanium, or any combination thereof.

22. The apparatus of claim 19, where the solidifying material comprises silica formed from a silica precursor.

23. The apparatus of claim 19, where the solidifying material comprises silica formed from the curing of aqueous solutions of silicates.

24. The apparatus of claim 19, where the size of the pores is modified by the space occupied by surfactant or other pore forming agent.

25. The apparatus of claim 19, where the porosity of the nanoparticle coating layer is based in whole or part on the void fraction resulting from packing density of the nanoparticles and reduction of pore spaces by the solidifying material.

26. The apparatus of claim 19, wherein the nanoparticle antireflective layer has a porosity of less than 60%.

27. The apparatus of claim 19, wherein the thickness of the nanoparticle antireflective coating layer is in a range from about 20 nanometers to 500 nanometers.

28. The apparatus of claim 19, wherein the solidifying material forms silica interparticle connections between adjacent nanoparticles and between at least some of the nanoparticles and the substrate to bind the nanoparticles to each other and to the substrate to form the antireflective coating.
